(19) United States
(12) Patent Application Publication
(10) Pub. No.: US 2026/0182351 A1
(43) Pub. Date: Jun. 25, 2026

(54) SEMICONDUCTOR DEVICE AND METHOD FOR FABRICATING THE SAME

(71) Applicant: Samsung Electronics Co., Ltd., Suwon-si (KR)

(72) Inventors: Ja Yeong HEO, Suwon-si (KR); Jun Sung KIM, Suwon-si (KR); Su Hyun BARK, Suwon-si (KR); Jong Min BAEK, Suwon-si (KR); Hoon Seok SEO, Suwon-si (KR); Kang Sub YIM, Suwon-si (KR)

(21) Appl. No.: 19/308,208

(22) Filed: Aug. 23, 2025

(30) Foreign Application Priority Data
Dec. 23, 2024 (KR) 10-2024-0193859

(51) Int. Cl. H01L 23/528; H01L 23/522; H01L 23/532

(52) U.S. Cl. CPC H10W 20/435; H10W 20/42; H10W 20/43; H10W 20/4451; H10W 20/48

(57) ABSTRACT

A semiconductor device includes a lower wiring structure disposed within a lower interlayer insulating film, and the lower wiring structure including a lower barrier film and a lower filling film disposed on the lower barrier film, a wiring isolation pattern extending along an upper surface of the lower interlayer insulating film, in contact with the lower interlayer insulating film, and the wiring isolation pattern including aluminum silicate, an upper interlayer insulating film disposed on the lower wiring structure and the wiring isolation pattern, and an upper wiring structure disposed within the upper interlayer insulating film and connected to the lower wiring structure.

### CROSS-REFERENCE TO RELATED APPLICATION(S)

This application claims priority from Korean Patent Application No. 10-2024-0193859 filed on Dec. 23, 2024 in the Korean Intellectual Property Office, and all the benefits accruing therefrom under 35 U.S.C. 119, the disclosure of which in its entirety is herein incorporated by reference.

### BACKGROUND

### 1. Technical Field

The present disclosure relates to a semiconductor device and a method for fabricating the same, and more particularly, to a semiconductor device including wiring lines formed during a back-end-of-line (BEOL) process and a method for fabricating the semiconductor device.

### 2. Description of the Related Art

Due to developments in electronic technology and the recent trend of down-scaling, high integration density and low power consumption are required of semiconductor chips. In order to meet these requirements, the feature size of semiconductor devices has continuously decreased.

As the feature size has decreased, various research has been conducted on ways to stably separate the wires.

### SUMMARY

An objective of the present disclosure is to provide a semiconductor device capable of improving device performance and reliability.

Another objective of the present disclosure is to provide a method for fabricating a semiconductor device capable of improving device performance and reliability.

The objectives of the present disclosure are not limited to those mentioned above, and other objectives not explicitly stated will be clearly understood by those skilled in the art based on the following description.

According to an aspect of the present disclosure, a semiconductor device includes a lower wiring structure disposed within a lower interlayer insulating film, and including a lower barrier film and a lower filling film disposed on the lower barrier film, a wiring isolation pattern extending along an upper surface of the lower interlayer insulating film, in contact with the lower interlayer insulating film, and including aluminum silicate, an upper interlayer insulating film disposed on the lower wiring structure and the wiring isolation pattern, and an upper wiring structure disposed within the upper interlayer insulating film and connected to the lower wiring structure.

According to another aspect of the present disclosure, a semiconductor device includes, a lower wiring structure disposed within a lower interlayer insulating film, a wiring isolation pattern disposed on an upper surface of the lower interlayer insulating film and including a lower wiring isolation pattern and an upper wiring isolation pattern disposed on the lower wiring isolation pattern, wherein the lower wiring isolation pattern is in contact with the lower interlayer insulating film, and the upper wiring isolation pattern includes aluminum silicate, an etch stop film disposed on the lower wiring structure and the wiring isolation pattern, and in contact with the upper wiring isolation pattern, an upper interlayer insulating film disposed on the etch stop film, and an upper wiring structure disposed within the upper interlayer insulating film and the etch stop film, and connected to the lower wiring structure.

According to another aspect of the present disclosure, a semiconductor device includes, a first wiring structure disposed within a first interlayer insulating film, a wiring isolation pattern extending along an upper surface of the first interlayer insulating film, in contact with the first interlayer insulating film, and including aluminum silicate, a first etch stop film disposed on the first wiring structure and the wiring isolation pattern, and in contact with the wiring isolation pattern, a second interlayer insulating film disposed on the first etch stop film, a second wiring structure disposed within the second interlayer insulating film and the first etch stop film, and connected to the first wiring structure, a second etch stop film disposed on the second wiring structure and the second interlayer insulating film, and in contact with an upper surface of the second interlayer insulating film, a third interlayer insulating film disposed on the second etch stop film, and a third wiring structure disposed within the third interlayer insulating film and the second etch stop film, and connected to the second wiring structure.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout diagram of a semiconductor device according to some embodiments.

FIG. 2 is an example cross-sectional view taken along line A-A of FIG. 1 according to some embodiments.

FIG. 3 is an example cross-sectional view taken along line B-B of FIG. 1 according to some embodiments.

FIG. 4 is a graph showing changes in the concentration of silicon (Si) along a scan line “SCAN LINE” of FIG. 2 according to some embodiments.

FIGS. 5 and 6 are diagrams illustrating a semiconductor device according to some embodiments.

FIGS. 7 and 8 are diagrams illustrating a semiconductor device according to some embodiments.

FIGS. 9 and 10 are diagrams illustrating a semiconductor device according to some embodiments.

FIGS. 11 and 12 are diagrams illustrating a semiconductor device according to some embodiments.

FIG. 13 is a diagram for explaining a semiconductor device according to some embodiments.

FIG. 14 is a diagram for explaining a semiconductor device according to some embodiments.

FIGS. 15 through 17 are diagrams illustrating a semiconductor device according to some embodiments.

FIGS. 18 through 26 are diagrams illustrating intermediate stages of a method for manufacturing a semiconductor device according to some embodiments.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The accompanying drawings illustrate, by way of example, a fin field-effect transistor (FinFET) including a fin pattern-shape channel region, a transistor containing nanowires or nanosheets, a Multi-Bridge Channel field-effect transistor (MBCFET™), and a vertical field-effect transistor (VFET), but are not limited thereto. Semiconductor devices according to some embodiments may also include a tunneling field-effect transistor (FET) and a three-dimensional (3D) transistor. Moreover, semiconductor devices according to some embodiments may include a planar transistor. Additionally, the technical concept of this disclosure may be applicable to a two-dimensional (2D) material-based FET and a heterostructure thereof.

Furthermore, semiconductor devices according to some embodiments may include a bipolar junction transistor and a laterally-diffused metal-oxide semiconductor (LDMOS).

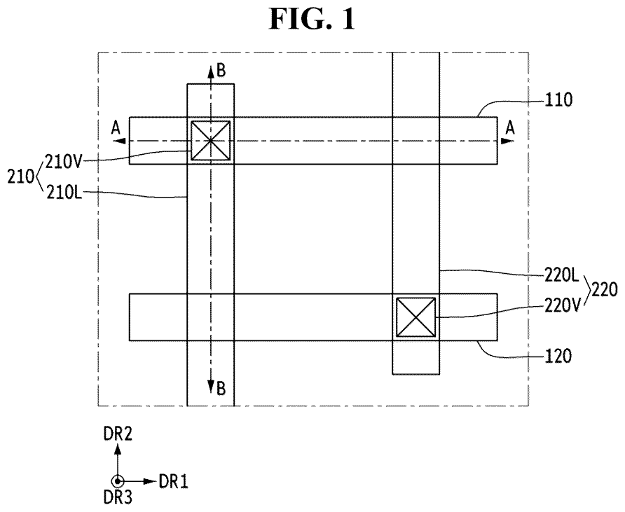

A semiconductor device according to some embodiments will hereinafter be described with reference to FIGS. 1 through 4.

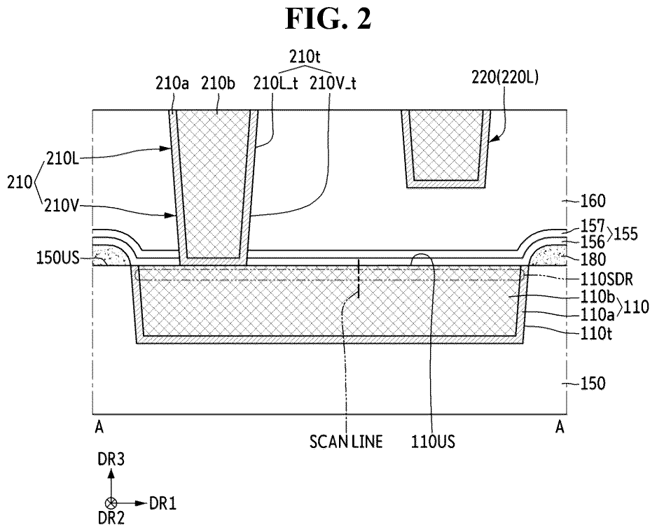

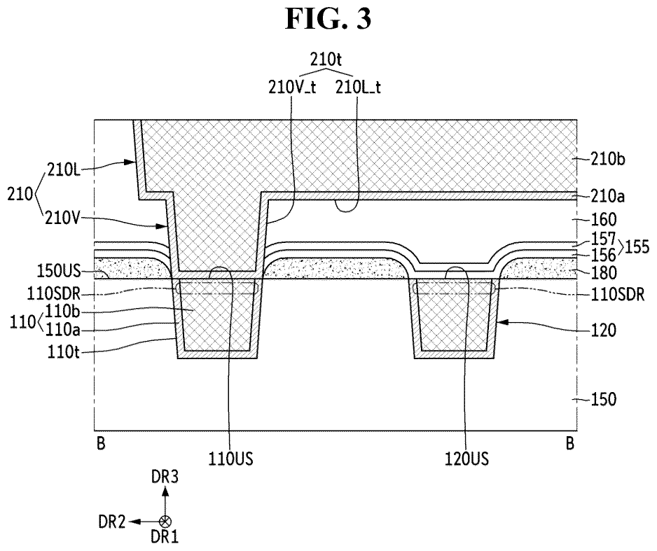

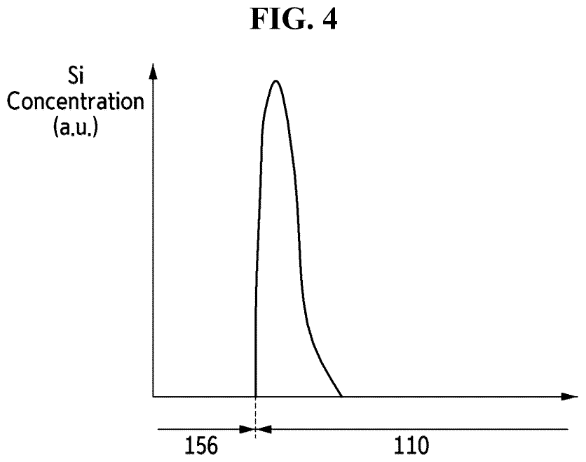

FIG. 1 is an example layout diagram of a semiconductor device according to some embodiments. FIG. 2 is an example cross-sectional view taken along line A-A of FIG. 1 according to some embodiments. FIG. 3 is an example cross-sectional view taken along line B-B of FIG. 1 according to some embodiments. FIG. 4 is a graph showing changes in the concentration of silicon (Si) along a scan line “SCAN LINE” of FIG. 2 according to some embodiments.

Referring to FIGS. 1 through 4, the semiconductor device according to some embodiments may include a first lower wiring structure 110, a second lower wiring structure 120, a first upper wiring structure 210, a second upper wiring structure 220, and a wiring isolation pattern 180.

The first and second lower wiring structures 110 and 120 may each be disposed within a first interlayer insulating film 150. The first and second lower wiring structures 110 and 120 may each extend in a first direction DR1. The first and second lower wiring structures 110 and 120 may be spaced apart in a second direction DR2.

The first and second lower wiring structures 110 and 120 may each have a line shape extending in the first direction DR1. For example, the first direction DR1 may represent the longitudinal direction of the first and second lower wiring structures 110 and 120, and the second direction DR2 may represent the width direction of the first and second lower wiring structures 110 and 120. Here, the first direction DR1 intersects the second direction DR2 and a third direction DR3, and the second direction DR2 intersects the third direction DR3.

The first and second lower wiring structures 110 and 120 are illustrated as being adjacent in the second direction DR2, but are not limited thereto. For example, an additional conductive lower pattern may be disposed between the first and second lower wiring structures 110 and 120. Additionally, the first and second lower wiring structures 110 and 120 in the first direction DR1 are illustrated as having the same length, but are not limited thereto.

The first interlayer insulating film 150 may cover gate electrodes and source/drain regions of transistors formed in a front-end-of-line (FEOL) process. Alternatively, the gate electrodes of transistors may be disposed within the first interlayer insulating film 150. Alternatively, the first interlayer insulating film 150 may be an interlayer insulating film formed in a back-end-of-line (BEOL) process.

In one example, the first and second lower wiring structures 110 and 120 may be contacts or contact wires formed in a middle-of-line (MOL) process. In another example, the first and second lower wiring structures 110 and 120 may be connection wires formed in a BEOL process. In yet another example, the first and second lower wiring structures 110 and 120 may be gate electrodes formed in an FEOL process.

The first and second lower wiring structures 110 and 120 will hereinafter be described as connection wires formed in a BEOL process.

The first interlayer insulating film 150 may include, for example, at least one of silicon oxide, silicon nitride, silicon oxynitride, and a low-k material. The low-k material may have a dielectric constant smaller than that of silicon oxide. For example, the low-k material may be a silicon oxide material with a relatively high carbon (C) and hydrogen (H) content, such as SiCOH. Carbon inclusion in an insulating material can reduce the dielectric constant of the insulating material. Furthermore, to further lower the dielectric constant, the insulating material may include pores, such as cavities filled with gas or air.

Examples of the low-k material may include fluorinated tetraethyl orthosilicate (FTEOS), hydrogen silsesquioxane (HSQ), bis-benzocyclobutene (BCB), tetramethyl orthosilicate (TMOS), octamethyl cyclotetrasiloxane (OMCTS), hexamethyldisiloxane (HMDS), trimethylsilyl borate (TMSB), diacetoxydi-tertiary-butoxysiloxane (DADBS), trimethylsilyl phosphate (TMSP), polytetrafluoroethylene (PTFE), tonen silazen (TOSZ), fluoride silicate glass (FSG), polypropylene oxide, polyimide nanofoams, carbon-doped silicon oxide (CDO), organosilicate glass (OSG), SiLK, amorphous fluorinated carbon, silica aerogels, silica xerogels, mesoporous silica, or combinations thereof, but are not limited thereto.

The first and second lower wiring structures 110 and 120 may be disposed at a first metal level. The first interlayer insulating film 150 may include lower wiring trenches 110t extending longitudinally in the first direction DR1.

The first and second lower wiring structures 110 and 120 may be disposed within the lower wiring trenches 110t. The first and second lower wiring structures 110 and 120 may fill the lower wiring trenches 110t.

The first and second lower wiring structures 110 and 120 may each include a lower barrier film 110a and a lower filling film 110b. The lower barrier film 110a may extend along the sidewalls and bottom surfaces of the lower wiring trenches 110t. The lower filling film 110b may be disposed on the lower barrier film 110a. The lower filling film 110b may fill the lower wiring trenches 110t.

The lower barrier film 110a may extend along the sidewalls and bottom surfaces of the lower filling film 110b. Alternatively, contrary to what is illustrated, the lower barrier film 110a may not be disposed on the sidewalls of the lower filling film 110b. Yet alternatively, the lower barrier film 110a may not be disposed on the bottom surface of the lower filling film 110b.

The lower barrier film 110a may include at least one of a metal, a conductive metal nitride, a conductive metal carbide, a conductive metal oxide, a conductive metal carbonitride, or a two-dimensional (2D) material. For example, the lower barrier film 110a may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel-boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), molybdenum (Mo), and the 2D material, but is not limited thereto.

The 2D material may include a 2D allotrope or compound, such as graphene, boron nitride (BN), molybdenum disulfide, molybdenum selenide, tungsten disulfide, tungsten selenide, or tantalum disulfide, but is not limited thereto. The aforementioned 2D materials are example and non-limiting, and other 2D materials may be included in the semiconductor device according to some embodiments. The lower barrier film 110a is illustrated as a single layer, but is not limited thereto.

The lower filling film 110b may include a metal or a conductive compound containing a metal. For example, the lower filling film 110b may include at least one of aluminum (Al), copper (Cu), W, Co, Ru, Ag, gold (Au), manganese (Mn), Mo, Rh, Ir, RuAl, NiAl, NbB₂, MoB₂, TaB₂, V₂AlC, and CrAlC, but is not limited thereto. If the lower filling film 110b includes Cu, it may further include, for example, C, silver (Ag), Co, Ta, indium (In), tin (Sn), zinc (Zn), Mn, Ti, magnesium (Mg), chromium (Cr), germanium (Ge), strontium (Sr), Pt, Mg, Al, or Zr.

Although not illustrated, the semiconductor device according to some embodiments may further include via patterns connecting conductive patterns disposed below the lower wiring structure 110.

In some embodiments, the first and second lower wiring structures 110 and 120 may each include an Si-doped region 110SDR. The Si-doped region 110SDR may be disposed, for example, near upper surfaces 110US and 120US of the first and second lower wiring structures 110 and 120, respectively. The Si-doped region 110SDR may contact a first etch stop film 155 that will be described later, but are not limited thereto.

The lower barrier film 110a and the lower filling film 110b may include the Si-doped region 110SDR. The Si-doped region 110SDR may be formed across the lower barrier film 110a and the lower filling film 110b. As illustrated in FIGS. 2 and 4, the concentration (/cm³) of Si in the Si-doped region 110SDR may increase and then decrease as the distance from the upper surface 110US of the first lower wiring structure 110 increases.

The wiring isolation pattern 180 is disposed on the first interlayer insulating film 150. The wiring isolation pattern 180 may be placed on an upper surface 150US of the first interlayer insulating film 150. The wiring isolation pattern 180 may extend along the upper surface 150US of the first interlayer insulating film 150.

The wiring isolation pattern 180 is in contact with the first interlayer insulating film 150. Specifically, the wiring isolation pattern 180 may contact the upper surface 150US of the first interlayer insulating film 150.

The wiring isolation pattern 180 may be disposed between the first and second lower wiring structures 110 and 120, which are adjacent in the second direction DR2. The wiring isolation pattern 180 may not be disposed on the first and second lower wiring structures 110 and 120. For example, the wiring isolation pattern 180 may not be placed on the upper surfaces 110US and 120US of the first and second lower wiring structures 110 and 120.

As the wiring isolation pattern 180 does not extend along the upper surfaces 110US and 120US of the first and second lower wiring structures 110 and 120, it may not contact these upper surfaces 110US and 120US of the first and second lower wiring structures 110 and 120.

The wiring isolation pattern 180 may not contact, for example, portions of the upper surface 110US of the first lower wiring structure 110 defined by the lower barrier film 110a and the lower filling film 110b.

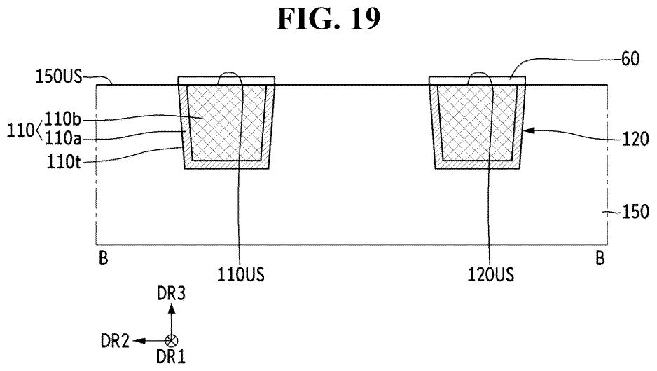

Contrary to what is illustrated, the wiring isolation pattern 180 may not be placed on the portion of the upper surface 110US defined by the lower filling film 110b, but may be placed on the portion of the upper surface 110US defined by the lower barrier film 110a. If a selective suppression film (e.g., 60 in FIG. 19) is formed only on the portions of the upper surfaces 110US and 120US of the first and second lower wiring structures 110 and 120 defined by the lower filling film 110b during the formation of the wiring isolation pattern 180, the wiring isolation pattern 180 may be formed on the portions of the upper surfaces 110US and 120US defined by the lower barrier film 110a.

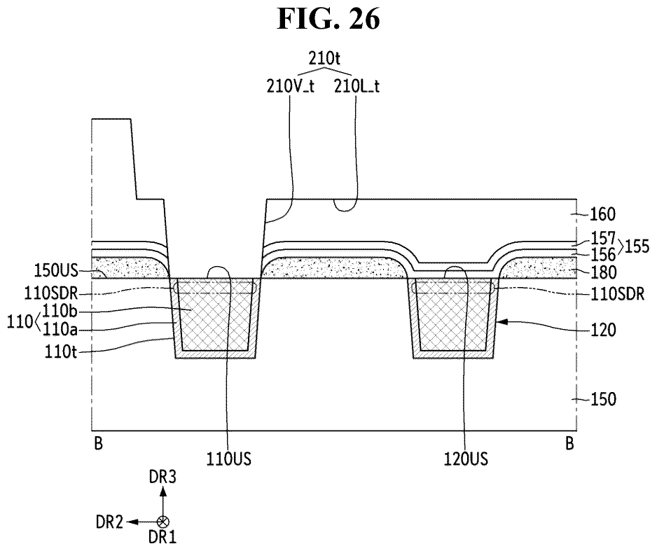

As the wiring isolation pattern 180 is formed on the upper surface 150US of the first interlayer insulating film 150 before forming the first etch stop film 155, a misalignment margin for a first upper via 210V formed in an upper wiring trench (210t in FIG. 26) with the second lower wiring structure 120 can be secured. For example, shorts between the first upper via 210V and the second lower wiring structure 120 can be prevented that may be caused by misalignment between the first upper via 210V and the first lower wiring structure 110. Alternatively, an increase in capacitance between the first upper via 210V and the second lower wiring structure 120 can be prevented that may be caused by misalignment between the first upper via 210V and the first lower wiring structure 110. Accordingly, the reliability and performance of the semiconductor device according to some embodiments can be improved.

For example, the first etch stop film 155 may include a lower etch stop film 156 and an upper etch stop film 157.

The wiring isolation pattern 180 may include aluminum silicate. In the semiconductor device according to some embodiments, the wiring isolation pattern 180 may have a single-layer structure. The wiring isolation pattern 180 may have a single insulating layer structure. For example, the wiring isolation pattern 180 may be formed of aluminum silicate.

For example, the wiring isolation pattern 180 may include 1 to 10 atomic percent (at. %) of Si.

If the wiring isolation pattern 180 includes less than 1 at. % of silicon, the etch selectivity between the wiring isolation pattern 180 and the lower etch stop film 156 may be low. As a result, during the formation of the upper wiring trench 210t, at least a portion of the wiring isolation pattern 180 may be removed. In this case, the short circuit or the reduced separation distance between the first upper via 210V formed in the first upper wiring trench 210t and the second lower wiring structure 120 may degrade the performance and reliability of the semiconductor device according to some embodiments.

If the wiring isolation pattern 180 includes more than 10 at. % of Si, the Si-doped region 110SDR included in each of the first and second lower wiring structures 110 and 120 may have a high Si concentration. The doping of high-concentration Si in the upper portions of the first and second lower wiring structures 110 and 120 may increase the wiring resistance of the first and second lower wiring structures 110 and 120. Consequently, the performance and reliability of the semiconductor device according to some embodiments may deteriorate.

The first etch stop film 155 may be disposed on the first lower wiring structure 110, the second lower wiring structure 120, and the wiring isolation pattern 180. The wiring isolation pattern 180 is disposed between the first etch stop film 155 and the first interlayer insulating film 150.

The first etch stop film 155 may extend along the profile of the wiring isolation pattern 180 and along the upper surfaces 110US and 120US of the first and second lower wiring structures 110 and 120. The first etch stop film 155 may contact the wiring isolation pattern 180.

The lower etch stop film 156 may be disposed on the first lower wiring structure 110, the second lower wiring structure 120, and the wiring isolation pattern 180. The lower etch stop film 156 may be disposed between the wiring isolation pattern 180 and the upper etch stop film 157, between the first lower wiring structure 110 and the upper etch stop film 157, and between the second lower wiring structure 120 and the upper etch stop film 157. The lower etch stop film 156 may contact the wiring isolation pattern 180.

The upper etch stop film 157 may be disposed on the lower etch stop film 156. The upper etch stop film 157 may be disposed between the lower etch stop film 156 and a second interlayer insulating film 160.

The first etch stop film 155 may include Al. The lower etch stop film 156 may include Al. For example, the lower etch stop film 156 may include aluminum oxide or aluminum nitride. For example, the lower etch stop film 156 may be formed of aluminum oxide or aluminum nitride. The upper etch stop film 157 may include a material with an etch selectivity with respect to the second interlayer insulating film 160. For example, the upper etch stop film 157 may include silicon oxycarbide, but is not limited thereto. Here, the silicon oxycarbide may be carbon-doped silicon oxide.

Contrary to what is illustrated, the first etch stop film 155 may have a single-layer structure rather than a multi-layer structure. If the first etch stop film 155 has a single-layer structure, it may include, for example, silicon nitride, silicon oxynitride, silicon oxycarbonitride, silicon boron nitride, silicon oxyboron nitride, silicon oxycarbide, aluminum oxide, aluminum nitride, aluminum oxycarbide, or a combination thereof.

The second interlayer insulating film 160 may be disposed on the wiring isolation pattern 180, the first lower wiring structure 110, and the second lower wiring structure 120. The second interlayer insulating film 160 may also be disposed on the first etch stop film 155. For example, the second interlayer insulating film 160 may be disposed on the upper etch stop film 157.

The first etch stop film 155 may be disposed between the first and second interlayer insulating films 150 and 160. The first etch stop film 155 may be disposed between the wiring isolation pattern 180 and the second interlayer insulating film 160, between the first lower wiring structure 110 and the second interlayer insulating film 160, and between the second lower wiring structure 120 and the second interlayer insulating film 160.

The first and second upper wiring structures 210 and 220 may be disposed above the first and second lower wiring structures 110 and 120. The first and second upper wiring structures 210 and 220 may be spaced apart from the first and second lower wiring structures 110 and 120 in the third direction DR3.

The first and second upper wiring structures 210 and 220 may be disposed within the second interlayer insulating film 160. Specifically, the first and second upper wiring structures 210 and 220 may be disposed within the first etch stop film 155 and the second interlayer insulating film 160.

For example, the first upper wiring structure 210 may be connected to the first lower wiring structure 110, and the second upper wiring structure 220 may be connected to the second lower wiring structure 120. For example, the first upper wiring structure 210 may contact the lower filling film 110b of the first lower wiring structure 110, and the second upper wiring structure 220 may contact the lower filling film 110b of the second lower wiring structure 120. The first upper wiring structure 210 may include a first upper wiring line 210L and the first upper via 210V. The second upper wiring structure 220 may include a second upper wiring line 220L and a second upper via 220V. The first and second upper wiring structures 210 and 220 may be disposed at a second metal level higher than the first metal level. For example, the first and second upper wiring lines 210L and 220L of the upper wiring structures 210 and 220 may be disposed at the second metal level.

The first upper wiring line 210L may extend in the second direction DR2. The first upper via 210V may be disposed between the first upper wiring line 210L and the first lower wiring structure 110. The first upper wiring line 210L may be disposed above the first upper via 210V. The first upper via 210V connects the first lower wiring structure 110 to the first upper wiring line 210L.

The second upper wiring line 220L may extend in the second direction DR2. The second upper wiring line 220L may be spaced apart from the first upper wiring line 210L in the first direction DR1. Although not illustrated, the second upper via 220V may be disposed between the second upper wiring line 220L and the second lower wiring structure 120. The second upper wiring line 220L may be disposed above the second upper via 220V. The second upper via 220V connects the second lower wiring structure 120 to the second upper wiring line 220L.

The structure of the second upper wiring structure 220 may be substantially the same as that of the first upper wiring structure 210. The following description focuses on the first upper wiring line 210L and the first upper via 210V included in the first upper wiring structure 210. The content related to the second upper wiring line 220L may be substantially the same as that related to the first upper wiring line 210L, and the content related to the second upper via 220V may be substantially the same as that related to the first upper via 210V.

The second interlayer insulating film 160 may include the first upper wiring trench 210t. The first upper wiring trench 210t may pass through the first etch stop film 155. The first upper wiring trench 210t may expose a portion of the first lower wiring structure 110. The first upper wiring trench 210t may expose a portion of the upper surface 110US of the first lower wiring structure 110.

The first upper wiring trench 210t may include a first upper via trench 210V_t and a first upper wiring line trench 210L_t. The first upper wiring line trench 210L_t may extend longitudinally in the second direction DR2. The first upper wiring line trench 210L_t may extend to the upper surface of the second interlayer insulating film 160. The first upper via trench 210V_t may be formed at the bottom surface of the first upper wiring line trench 210L_t.

For example, the bottom surface of the first upper wiring trench 210t may be the bottom surface of the first upper via trench 210V_t. In the semiconductor device according to some embodiments, the bottom surface of the first upper wiring trench 210t may be defined by the upper surface 110US of the first lower wiring structure 110, which is defined by the lower filling film 110b.

The sidewalls of the first upper wiring trench 210t may include the sidewalls and bottom surface of the first upper wiring line trench 210L_t and the sidewalls of the first upper via trench 210V_t. The sidewalls and bottom surface of the first upper wiring line trench 210L_t may be defined by the second interlayer insulating film 160. The sidewalls of the first upper via trench 210V_t may be defined by the second interlayer insulating film 160 and the first etch stop film 155.

The second interlayer insulating film 160 may include, for example, at least one of silicon oxide, silicon nitride, silicon oxynitride, and a low-k material.

The first and second upper wiring structures 210 and 220 may each be disposed within the first upper wiring trench 210t. The first and second upper wiring structures 210 and 220 may each fill the first upper wiring trench 210t.

The first upper wiring structure 210 may fill the first upper via trench 210V_t and the first upper wiring line trench 210L_t. The first upper wiring line 210L may be disposed within the first upper wiring line trench 210L_t, and the first upper via 210V may be disposed within the first upper via trench 210V_t.

The first and second upper wiring structures 210 and 220 may each include a first upper barrier film 210a and a first upper filling film 210b.

The first upper barrier film 210a may extend along the sidewalls and bottom surface of the first upper wiring trench 210t. The first upper barrier film 210a may extend along the sidewalls and bottom surface of the first upper wiring line trench 210L_t and the sidewalls and bottom surface of the first upper via trench 210V_t.

The first upper filling film 210b may be disposed on the first upper barrier film 210a. The first upper filling film 210b may fill the remaining space in the first upper wiring trench 210t.

The first and second upper wiring lines 210L and 220L may each include the first upper barrier film 210a and the first upper filling film 210b. The first and second upper vias 210V and 220V may also include the first upper barrier film 210a and the first upper filling film 210b.

The first upper barrier film 210a may include at least one of a metal, a conductive metal nitride, a conductive metal carbide, a conductive metal oxide, a conductive metal carbonitride, and a 2D material. The first upper filling film 210b may include a metal or a conductive compound containing a metal. The first upper barrier film 210a is illustrated as a single layer, but is not limited thereto.

Contrary to what is illustrated, the first upper barrier film 210a may not extend along the bottom surface of the first upper via trench 210V_t. In this case, the first upper filling film 210b may contact the first lower wiring structure 110.

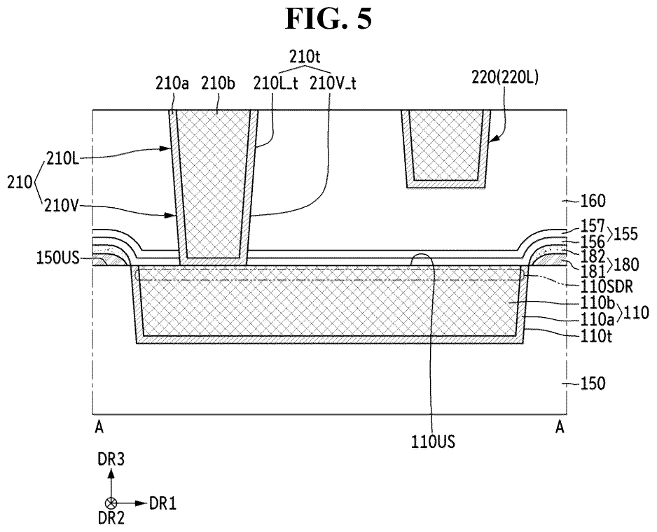

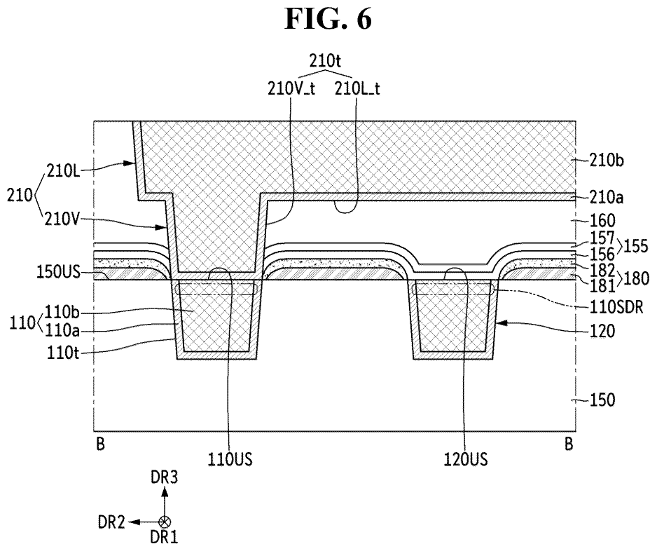

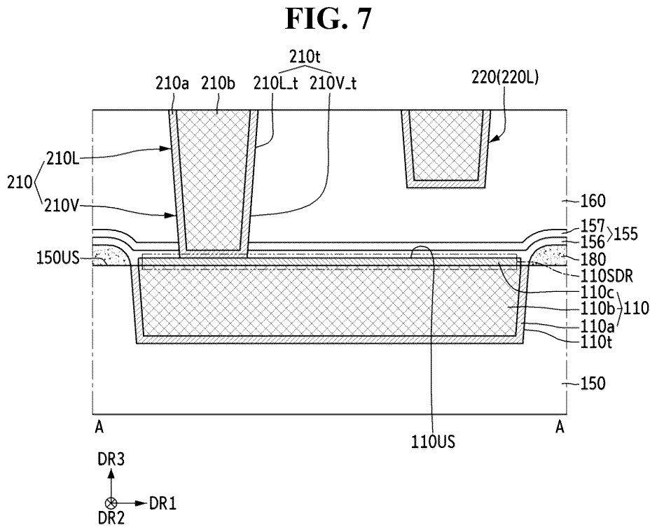

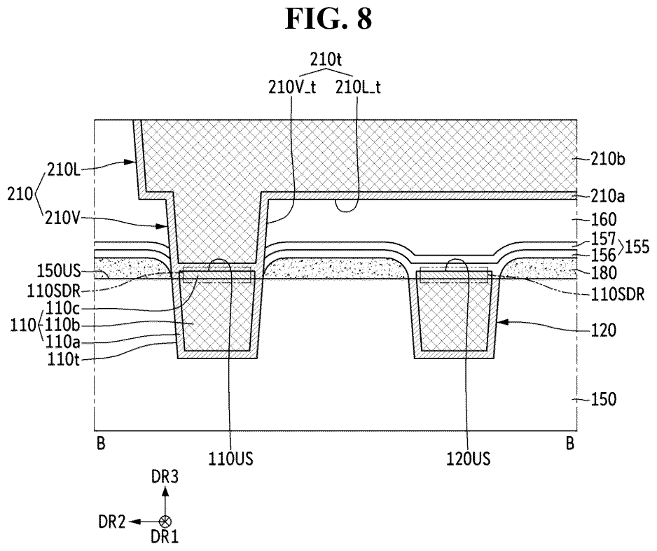

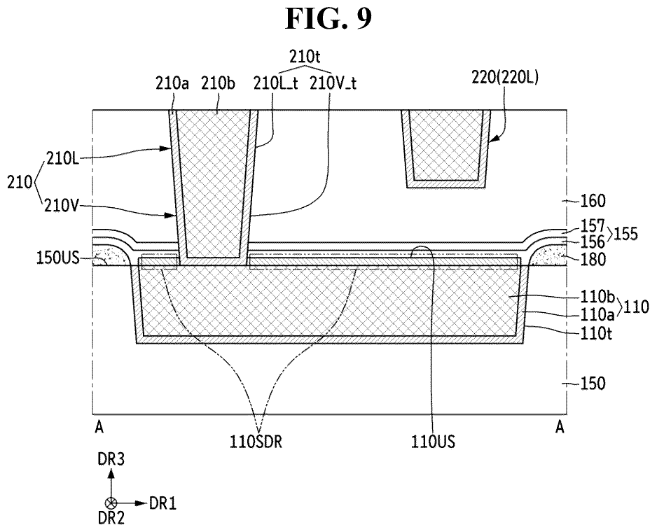

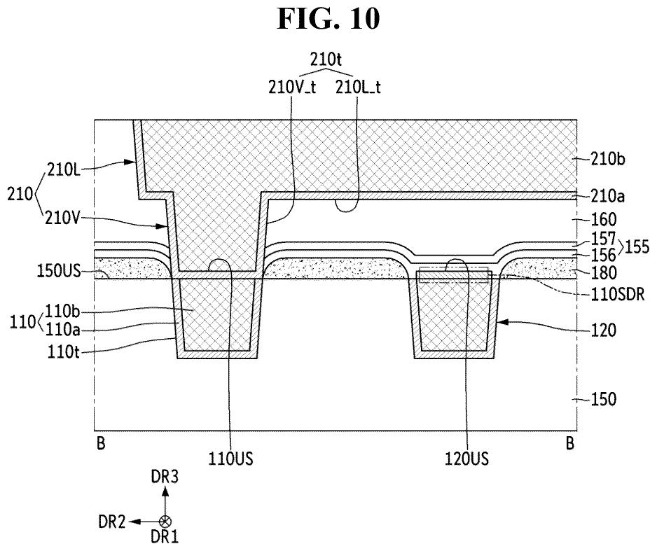

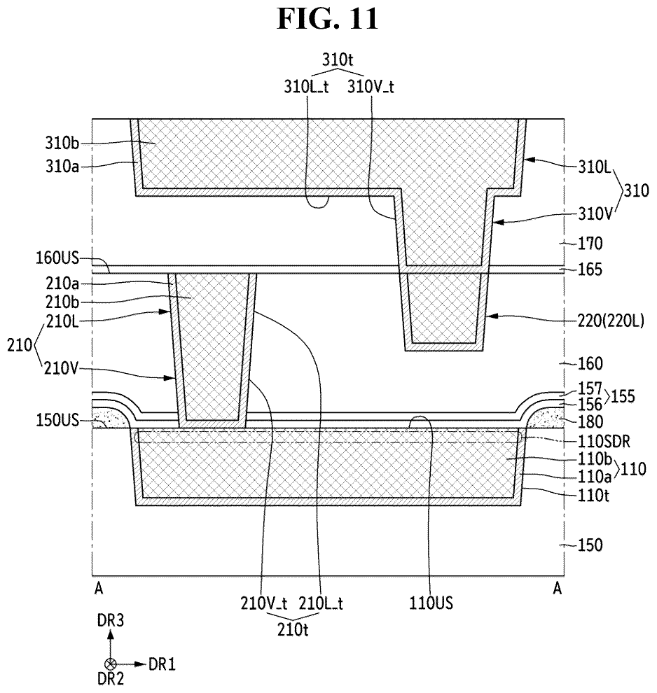

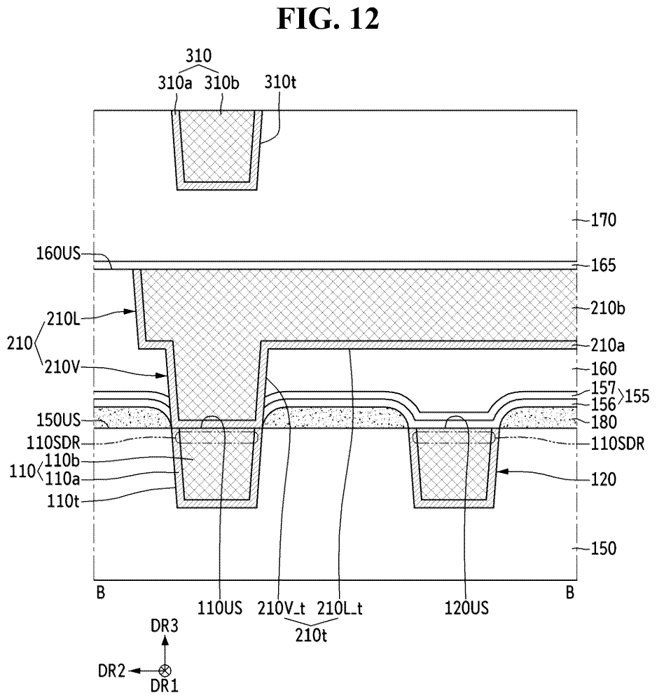

FIGS. 5 and 6 are diagrams illustrating a semiconductor device according to some embodiments. FIGS. 7 and 8 are diagrams illustrating a semiconductor device according to some embodiments. FIGS. 9 and 10 are diagrams illustrating a semiconductor device according to some embodiments. FIGS. 11 and 12 are diagrams illustrating a semiconductor device according to some embodiments. For convenience, the embodiments of FIGS. 5 through 12 will hereinafter be described, focusing mainly on differences from the embodiment of FIGS. 1 through 4.

Referring to FIGS. 5 and 6, in the semiconductor device according to some embodiments, a wiring isolation pattern 180 may include a lower wiring isolation pattern 181 and an upper wiring isolation pattern 182.

The lower wiring isolation pattern 181 may be disposed on a first interlayer insulating film 150. The lower wiring isolation pattern 181 may be disposed between the first interlayer insulating film 150 and the upper wiring isolation pattern 182. The lower wiring isolation pattern 181 may contact an upper surface 150US of the first interlayer insulating film 150.

The upper wiring isolation pattern 182 may be disposed on the lower wiring isolation pattern 181. The upper wiring isolation pattern 182 may contact the lower wiring isolation pattern 181.

The upper wiring isolation pattern 182 may be disposed between the lower wiring isolation pattern 181 and a second interlayer insulating film 160. Specifically, the upper wiring isolation pattern 182 may be disposed between the lower wiring isolation pattern 181 and a first etch stop film 155.

For example, the upper wiring isolation pattern 182 may cover the entire upper surface of the lower wiring isolation pattern 181. From a cross-sectional perspective, the lower wiring isolation pattern 181 may be surrounded by the upper wiring isolation pattern 182 and the first interlayer insulating film 150, but is not limited thereto.

The upper wiring isolation pattern 182 may contact the first etch stop film 155. The upper wiring isolation pattern 182 may contact the lower etch stop film 156.

The lower wiring isolation pattern 181 may include aluminum oxide. For example, the lower wiring isolation pattern 181 may be formed of aluminum oxide.

The upper wiring isolation pattern 182 may include aluminum silicate. For example, the upper wiring isolation pattern 182 may be formed of aluminum silicate. The upper wiring isolation pattern 182 may include 1 at. % to 10 at. % of Si.

Referring to FIGS. 7 through 10, in the semiconductor device according to some embodiments, a first lower wiring structure 110 and a second lower wiring structure 120 may each further include a lower capping film 110c.

The lower capping film 110c may be disposed on the lower filling film 110b. The lower capping film 110c may extend along the upper surface of the lower filling film 110b.

The lower capping film 110c may include an upper surface 110US of the first lower wiring structure 110 and an upper surface 120US of the second lower wiring structure 120. The lower capping film 110c may include a Si-doped region 110SDR of each of the first and second lower wiring structures 110 and 120.

The lower capping film 110c may not cover the upper surface of the lower barrier film 110a. Contrary to what is illustrated, the lower capping film 110c may cover at least a portion of the upper surface of the lower barrier film 110a.

The lower capping film 110c may include a conductive material, for example, a metal. The lower capping film 110c may, for example, include Co.

In FIGS. 7 and 8, the first upper wiring structure 210 may not penetrate the lower capping film 110c. The first upper wiring structure 210 may not contact the lower filling film 110b. The first upper wiring structure 210 may be connected to the first lower wiring structure 110 through the lower capping film 110c.

In FIGS. 9 and 10, the first upper wiring structure 210 may penetrate the lower capping film 110c. The first upper wiring structure 210 may contact the lower filling film 110b.

Referring to FIGS. 11 and 12, the semiconductor device according to some embodiments may further include a third upper wiring structure 310 connected to a second upper wiring structure 220.

A second etch stop film 165 may be disposed on a first upper wiring structure 210, the second upper wiring structure 220, and a second interlayer insulating film 160. The second etch stop film 165 may extend along an upper surface 160US of the second interlayer insulating film 160, the upper surface of the first upper wiring structure 210, and the upper surface of the second upper wiring structure 220. The second etch stop film 165 may contact the upper surface 160US of the second interlayer insulating film 160.

The second etch stop film 165 may include a material with an etch selectivity relative to a third interlayer insulating film 170. The second etch stop film 165 may include, for example, at least one of silicon nitride, silicon oxynitride, silicon oxycarbonitride, silicon boron nitride, silicon oxyboron nitride, silicon oxycarbide, aluminum oxide, aluminum nitride, aluminum oxycarbide, and a combination thereof.

The second etch stop film 165 is illustrated as a single layer, but is not limited thereto. Contrary to what is illustrated, the second etch stop film 165 may include a plurality of insulating films sequentially stacked on the second interlayer insulating film 160, similar to a first etch stop film 155.

The third interlayer insulating film 170 may be disposed on the second etch stop film 165. The third interlayer insulating film 170 may be disposed on the first and second upper wiring structures 210 and 220.

The third interlayer insulating film 170 may include, for example, at least one of silicon oxide, silicon nitride, silicon oxynitride, and a low-k material.

The third upper wiring structure 310 may be disposed above the first and second upper wiring structures 210 and 220. The third upper wiring structure 310 may be spaced apart from the first and second upper wiring structures 210 and 220 in the third direction DR3. The third upper wiring structure 310 may be disposed within the third interlayer insulating film 170. Specifically, the third upper wiring structure 310 may be disposed within the second etch stop film 165 and the third interlayer insulating film 170.

For example, the third upper wiring structure 310 may be connected to the second upper wiring structure 220. The third upper wiring structure 310 may contact the second upper wiring structure 220. For example, the third upper wiring structure 310 may contact the first upper filling film 210b of the second upper wiring structure 220. The third upper wiring structure 310 may include a third upper wiring line 310L and a third upper via 310V. The third upper wiring structure 310 may be disposed at a third metal level higher than the second metal level. For example, the third upper wiring line 310L of the third upper wiring structure 310 may be disposed at the third metal level.

The third upper wiring line 310L may extend in the first direction DR1. The third upper via 310V may be disposed between a second upper wiring line 220L of the second upper wiring structure 220 and the third upper wiring line 310L. The third upper wiring line 310L may be disposed above the third upper via 310V. The third upper via 310V connects the second upper wiring line 220L to the third upper wiring line 310L.

The third interlayer insulating film 170 may include a second upper wiring trench 310t. The second upper wiring trench 310t may pass through the second etch stop film 165. The second upper wiring trench 310t may expose the second upper wiring line 220L. Similar to how the first upper wiring trench 210t exposes the portion of the upper surface 110US of the first lower wiring structure 110, as illustrated in FIG. 2, the second upper wiring trench 310t may expose a portion of the upper surface of the second upper wiring line 220L.

The second upper wiring trench 310t may include a second upper via trench 310V_t and a second upper wiring line trench 310L_t. The second upper wiring line trench 310L_t may extend longitudinally in the first direction DR1. The second upper wiring line trench 310L_t may extend to the upper surface of a third interlayer insulating film 170. The second upper via trench 310V_t may be formed at the bottom surface of the second upper wiring line trench 310L_t.

The sidewalls of the second upper wiring trench 310t may include the sidewalls and bottom surface of the second upper wiring line trench 310L_t and the sidewalls of the second upper via trench 310V_t. The sidewalls and bottom surface of the second upper wiring line trench 310L_t may be defined by the third interlayer insulating film 170. The sidewalls of the second upper via trench 310V_t may be defined by the third interlayer insulating film 170 and the second etch stop film 165.

The third upper wiring structure 310 may be disposed within the second upper wiring trench 310t. The third upper wiring structure 310 may fill the second upper wiring trench 310t.

The third upper wiring structure 310 may fill the second upper via trench 310V_t and the second upper wiring line trench 310L_t. The third upper wiring line 310L may be disposed within the second upper wiring line trench 310L_t, and the third upper via 310V may be disposed within the second upper via trench 310V_t.

The third upper wiring structure 310 may include a second upper barrier film 310a and a second upper filling film 310b.

The second upper barrier film 310a may extend along the sidewalls and bottom surface of the second upper wiring trench 310t. The second upper barrier film 310a may extend along the sidewalls and bottom surface of the second upper wiring line trench 310L_t and the sidewalls and bottom surface of the second upper via trench 310V_t.

The second upper filling film 310b may be disposed on the second upper barrier film 310a. The second upper filling film 310b may fill the remaining space in the second upper wiring trench 310t.

The third upper wiring line 310L may include the second upper barrier film 310a and the second upper filling film 310b. The third upper via 310V may include the second upper barrier film 310a and the second upper filling film 310b.

The second upper barrier film 310a may include at least one of a metal, a conductive metal nitride, a conductive metal carbide, a conductive metal oxide, a conductive metal carbonitride, and a 2D material. The second upper filling film 310b may include a metal or a conductive compound containing a metal. The second upper barrier film 310a is illustrated as a single layer, but is not limited thereto.

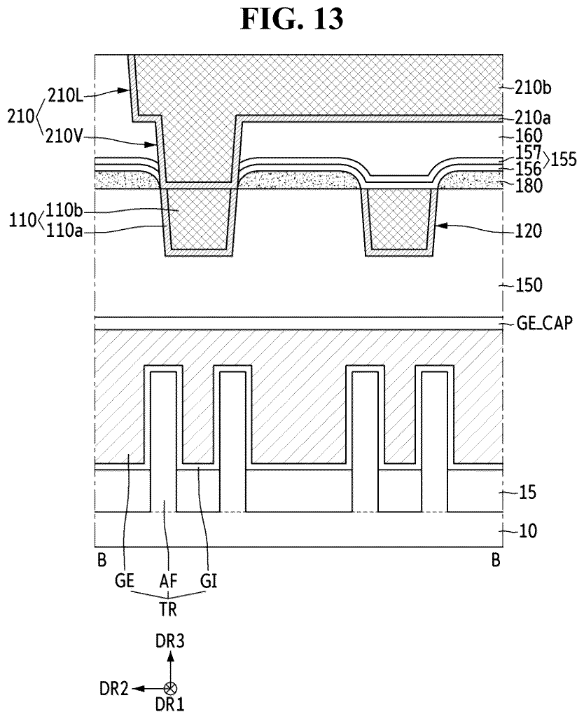

FIG. 13 is a diagram for explaining a semiconductor device according to some embodiments. For convenience, the semiconductor device of FIG. 13 will hereinafter be described, focusing mainly on the differences from the semiconductor device of FIGS. 1 through 4.

Specifically, FIG. 13 is a cross-sectional view taken across a first gate electrode GE.

In FIG. 13, fin-type patterns AF may extend in a first direction DR1, and the first gate electrode GE may extend in a second direction DR2. However, the present disclosure is not limited to this.

Referring to FIG. 13, the semiconductor device according to some embodiments may include transistors TR, which are disposed between a substrate 10 and a first lower wiring structure 110.

The substrate 10 may be an Si substrate or an Si-on-insulator (SOI). Alternatively, the substrate 10 may include silicon-germanium (SiGe), an SiGe-on-insulator (SGOI), indium antimonide, a lead tellurium compound, indium arsenide, indium phosphide, gallium arsenide, or gallium antimonide, but is not limited thereto.

The transistors TR may include the fin-type patterns AF, the first gate electrode GE, which is on the fin-type patterns AF, and a first gate insulating film GI, which is disposed between the first gate electrode GE and the fin-type patterns AF.

Although not specifically illustrated, the transistors TR may include source/drain patterns disposed on both sides of the first gate electrode GE.

The fin-type patterns AF may protrude from the substrate 10. The fin-type patterns AF may extend in the first direction DR1. The fin-type patterns AF may be parts of the substrate 10 or may include an epitaxial layer grown from the substrate 10. The fin-type patterns AF may include, for example, an element semiconductor material such as Si or Ge. Alternatively, the fin-type patterns AF may include a compound semiconductor such as, for example, a Group IV-IV compound semiconductor or a Group III-V compound semiconductor.

The Group IV-IV compound semiconductor may be a binary or ternary compound including at least two of C, Si, Ge, and Sn and a compound obtained by doping the binary or ternary compound with a Group IV element. The Group III-V compound semiconductor may be a binary, ternary, or quaternary compound obtained by combining at least one group III element such as Al, gallium (Ga), or In and a Group V element such as phosphorus (P), arsenic (As), or antimony (Sb).

A field insulating film 15 may be disposed on the substrate 10. The field insulating film 15 may be formed on parts of the sidewalls of each of the fin-type patterns AF. The fin-type patterns AF may protrude beyond the top surface of the field insulating film 15. The field insulating film 15 may include, for example, an oxide film, a nitride film, an oxynitride film, or a combination thereof.

The first gate electrode GE may be disposed on the fin-type patterns AF. The first gate electrode GE may extend in the second direction DR2. The first gate electrode GE may intersect the fin-type patterns AF.

The first gate electrode GE may include at least one of, for example, a metal, a conductive metal nitride, a conductive metal carbonitride, a conductive metal carbide, a metal silicide, a doped semiconductor material, a conductive metal oxynitride, and a conductive metal oxide.

The first gate insulating film GI may be disposed between the first gate electrode GE and the fin-type patterns AF and between the first gate electrode GE and the field insulating film 15. The first gate insulating film GI may include, for example, silicon oxide, silicon oxynitride, silicon nitride, or a high-k material having a greater dielectric constant than silicon oxide. The high-k material may include at least one of, for example, boron nitride, a metal oxide, and a metal silicon oxide, but is not limited thereto.

The semiconductor device according to some embodiments may include negative capacitance (NC) FETs using negative capacitors. For example, the first gate insulating film GI may include a ferroelectric material film having ferroelectric properties and a paraelectric material film having paraelectric properties.

The ferroelectric material film may have negative capacitance, and the paraelectric material film may have positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having negative capacitance and the paraelectric material film having positive capacitance are connected in series, the total capacitance of the ferroelectric material film and the paraelectric material film may increase. Accordingly, a transistor having the ferroelectric material film can have a sub-threshold swing (SS) of less than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. For example, the hafnium zirconium oxide may be a material obtained by doping hafnium oxide with Zr. In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), Mg, Si, calcium (Ca), cerium (Ce), dysprosium (Dy), erbium (Er), gadolinium (Gd), germanium, scandium (Sc), Sr, and Sn. The type of dopant may vary depending on the type of material of the ferroelectric material film.

If the ferroelectric material film includes hafnium oxide, the dopant of the ferroelectric material film may include, for example, at least one of Gd, Si, Zr, Al, and Y.

If the dopant of the ferroelectric material film is Al, the ferroelectric material film may include 3 atomic % (at %) to 8 at % of Al. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include 2 at % to 10 at % of Si. If the dopant of the ferroelectric material film is Y, the ferroelectric material film may include 2 at % to 10 at % of Y. If the dopant of the ferroelectric material film is Gd, the ferroelectric material film may include 1 at % to 7 at % of Gd. If the dopant of the ferroelectric material film is Zr, the ferroelectric material film may include 50 at % to 80 at % of Zr.

The paraelectric material film may include paraelectric properties. The paraelectric material film may include, for example, at least one of silicon oxide and a high-k metal oxide. The high-k metal oxide may include, for example, at least one of hafnium oxide, zirconium oxide, and aluminum oxide, but is not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, 0.5 nm to 10 nm, but is not limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, the first gate insulating film GI may include one ferroelectric material film. In another example, the first gate insulating film GI may include a plurality of ferroelectric material films that are spaced apart from one another. The first gate insulating film GI may have a structure in which a plurality of ferroelectric material films and a plurality of paraelectric material films are alternately stacked.

A gate capping pattern GE_CAP may be disposed on the first gate electrode GE. The first lower wiring structure 110 may be disposed on the first gate electrode GE. The first lower wiring structure 110 is illustrated as not being connected to the first gate electrode GE, but is not limited thereto.

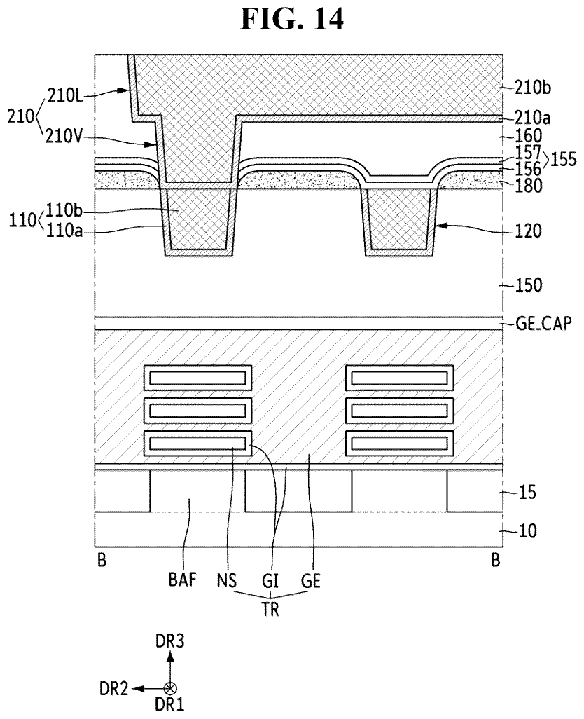

FIG. 14 is a diagram for explaining a semiconductor device according to some embodiments. For convenience, the semiconductor device of FIG. 14 will hereinafter be described, focusing mainly on the differences from the semiconductor device of FIG. 13.

Referring to FIG. 14, transistors TR may include nanosheets NS, a first gate electrode GE, which surrounds the nanosheets NS, and first gate insulating films GI, which are between the first gate electrode GE and the nanosheets NS.

The nanosheets NS may be disposed on lower fin-type patterns BAF. The nanosheets NS may be spaced apart from the lower fin-type patterns BAF in a third direction DR3. Each of the transistors TR is illustrated as, but is not limited to, including three nanosheets NS spaced apart from one another in the third direction DR3. Alternatively, more than three nanosheets NS, or less than three nanosheets NS, may be disposed on each of the lower fin-type patterns BAF in the third direction DR3.

The lower fin-type patterns BAF and the nanosheets NS may include an element semiconductor material such as, for example, Si or Ge. Each of the lower fin-type patterns BAF and the nanosheets NS may include a compound semiconductor such as, for example, a Group IV-IV compound semiconductor or a Group III-V compound semiconductor. The lower fin-type patterns BAF and the nanosheets NS may include the same material or may include different materials.

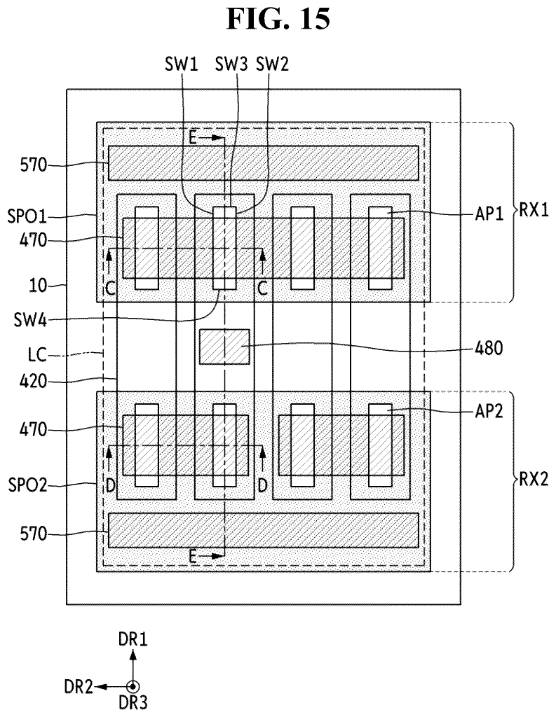

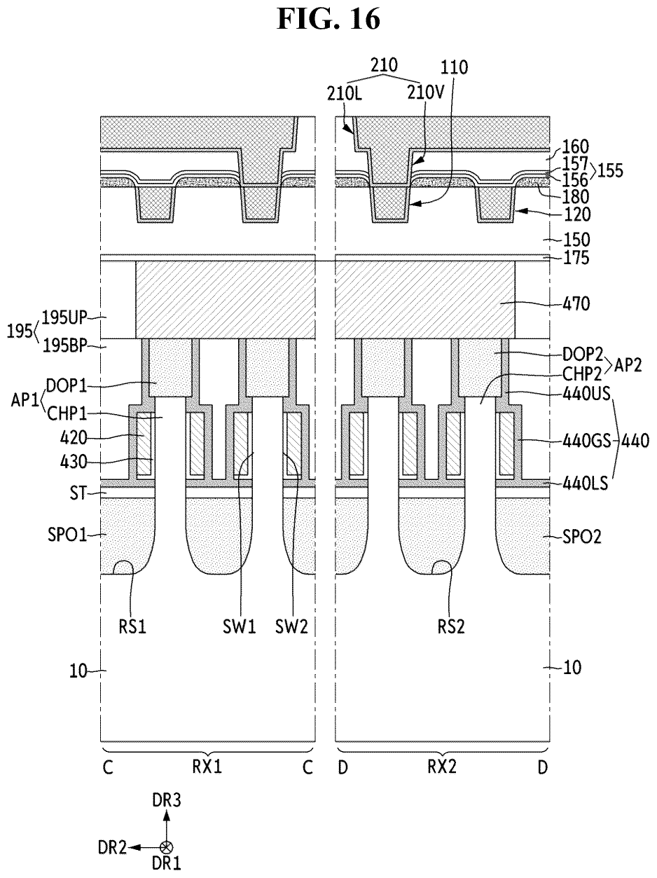

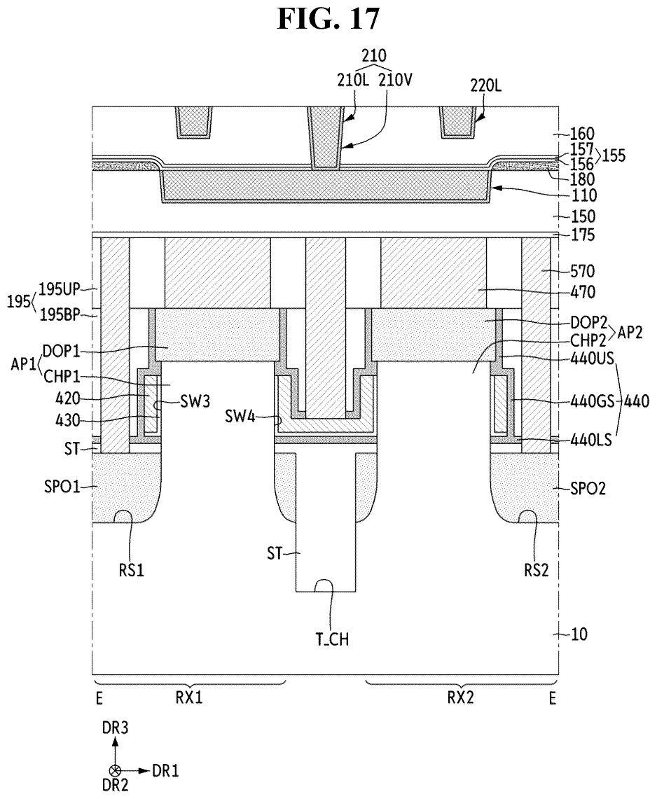

FIGS. 15 through 17 are diagrams illustrating a semiconductor device according to some embodiments. Specifically, FIG. 15 is a plan view for explaining a semiconductor device according to some embodiments, FIG. 16 is a cross-sectional view taken along lines C-C and D-D of FIG. 15 according to some embodiments, and FIG. 17 is a cross-sectional view taken along line E-E of FIG. 15 according to some embodiments.

Referring to FIGS. 15 through 17, a logic cell LC may be provided on a substrate 10. The logic cell LC may be a logic element (e.g., an inverter, a flipflop, or the like) performing a particular function. The logic cell LC may include VFETs, which form a logic element, and wires, which connect the VFETs.

The logic cell LC on the substrate 10 may include first and second active regions RX1 and RX2. For example, the first active region RX1 may be a P-type metal-oxide semiconductor (MOSFET) region, and the second active region RX2 may be an N-type MOSFET region. The first and second active regions RX1 and RX2 may be defined by a trench T_CH, which is formed in the substrate 10. The first and second active regions RX1 and RX2 may be spaced apart from each other in a first direction DR1.

A first lower epitaxial pattern SPO1 may be provided in the first active region RX1, and a second lower epitaxial pattern SPO2 may be provided in the second active region RX2. From a planar perspective, the first lower epitaxial pattern SPO1 may overlap with the first active region RX1, and the second lower epitaxial pattern SPO2 may overlap with the second active region RX2. The first and second lower epitaxial patterns SPO1 and SPO2 may be obtained by a selective epitaxial growth process. The first lower epitaxial pattern SPO1 may be provided in a first recess region RS1 of the substrate 10, and the second lower epitaxial pattern SPO2 may be provided in a second recess region RS2 of the substrate 10.

First active patterns AP1 may be provided in the first active region RX1, and second active patterns AP2 may be provided in the second active region RX2. The first active patterns AP1 and the second active patterns AP2 may each have a fin shape protruding vertically. From a planar perspective, the first active patterns AP1 and the second active patterns AP2 may each have a bar shape extending in the first direction DR1. The first active patterns AP1 may be arranged along the second direction DR2, and the second active patterns AP2 may be arranged along the second direction DR2.

The first active patterns AP1 may each include a first channel pattern CHP1 protruding vertically from the first lower epitaxial pattern SPO1, and a first upper epitaxial pattern DOP1 on the first channel pattern CHP1. The second active patterns AP2 may each include a second channel pattern CHP2 protruding vertically from the second lower epitaxial pattern SPO2, and a second upper epitaxial pattern DOP2 on the second channel pattern CHP2.

A device isolation film ST may be provided on the substrate 10 to fill the trench T_CH. The device isolation film ST may cover the top surfaces of the first and second lower epitaxial patterns SPO1 and SPO2. The first active patterns AP1 and the second active patterns AP2 may protrude vertically from the device isolation film ST.

A plurality of second gate electrodes 420, which extend in parallel to one another in the first direction DR1, may be provided on the device isolation film ST. The second gate electrodes 420 may be arranged along the second direction DR2. The second gate electrodes 420 may surround the first channel patterns CHP1 of the first active patterns AP1 and the second channel patterns CHP2 of the second active patterns AP2. For example, each of the first channel patterns CHP1 or each of the second channel patterns CHP2 may include first through fourth sidewalls SW1 through SW4. The first and second sidewalls SW1 and SW2 may be opposite to each other in the second direction DR2, and the third and fourth sidewalls SW3 and SW4 may be opposite to each other in the first direction DR1. The second gate electrodes 420 may be provided on the first through fourth sidewalls SW1 through SW4 of each of the first channel patterns CHP1. For example, the second gate electrodes 420 may surround the first through fourth sidewalls SW1 through SW4 of each of the first channel patterns CHP1. For example, the second gate electrodes 420 may surround the first through fourth sidewalls SW1 through SW4 of each of the second channel patterns CHP2.

Second gate insulating films 430 may be interposed between the second gate electrodes 420 and the first channel patterns CHP1, and between the second gate electrodes 420 and the second channel patterns CHP2. The second gate insulating films 430 may cover the bottom surface and the inner sidewalls of each of the second gate electrodes 420. For example, the second gate insulating films 430 may directly cover the first through fourth sidewalls SW1 through SW4 of each of the first active patterns AP1.

The first upper epitaxial patterns DOP1 and the second upper epitaxial patterns DOP2 may protrude vertically from the second gate electrodes 420. The top surfaces of the second gate electrodes 420 may be lower than the bottom surfaces of the first upper epitaxial patterns DOP1 and the bottom surfaces of the second upper epitaxial patterns DOP2. For example, the first active patterns AP1 and the second active patterns AP2 may protrude vertically from the substrate 10 to penetrate the second gate electrodes 420.

The semiconductor device according to some embodiments may include VFETs where carriers move in the third direction DR3. For example, when the VFETs are on in response to a voltage being applied to the second gate electrodes 420, carriers may move from the first or second lower epitaxial pattern SPO1 or SPO2 to the first or second upper epitaxial patterns DOP1 or DOP2 through the first or second channel patterns CHP1 or CHP2. The second gate electrodes 420 may surround the first through fourth sidewalls of each of the first or second channel patterns CHP1 or CHP2. The VFETs may have a gate-all-around structure. As channels are surrounded by gates, the semiconductor device according to some embodiments can have excellent electrical properties.

Spacers 440, which cover the second gate electrodes 420, the first active patterns AP1, and the second active patterns AP2, may be provided on the device isolation film ST. The spacers 440 may include silicon nitride or silicon oxynitride. The spacers 440 may include lower spacers 440LS, upper spacers 440US, and gate spacers 440GS between the lower spacers 440LS and the upper spacers 440US.

The lower spacers 440LS may directly cover the top surface of the device isolation film ST. Due to the lower spacers 440LS, the second gate electrodes 420 may be spaced apart from the device isolation film ST in the third direction DR3. The gate spacers 440GS may cover the top surfaces and the outer sidewalls of the second gate electrodes 420. The upper spacers 440US may cover the first upper epitaxial patterns DOP1 and the second upper epitaxial patterns DOP2. However, the upper spacers 440US may not cover but expose the top surfaces of the first upper epitaxial patterns DOP1 and the top surfaces of the second upper epitaxial patterns DOP2.

A first part 195BP of a lower interlayer insulating film 195 may be provided on the spacers 440. The top surface of the first part 195BP of the lower interlayer insulating film 195 may form substantially the same plane as the top surfaces of the first upper epitaxial patterns DOP1 and the top surfaces of the second upper epitaxial patterns DOP2. A second part 195UP of the lower interlayer insulating film 195, a first interlayer insulating film 150, and a second interlayer insulating film 160 may be sequentially stacked on the first part 195BP of the lower interlayer insulating film 195. The first and second parts 195BP and 195UP may be included in the lower interlayer insulating film 195. The second part 195UP of the lower interlayer insulating film 195 may cover the top surfaces of the first upper epitaxial patterns DOP1 and the top surfaces of the second upper epitaxial patterns DOP2.

One or more first source/drain contacts 470, which are connected to the first upper epitaxial patterns DOP1 and the second upper epitaxial patterns DOP2 through the second part 195UP of the lower interlayer insulating film 195, may be provided. One or more second source/drain contacts 570, which are connected to the first and second lower epitaxial patterns SPO1 and SPO2 sequentially through the lower interlayer insulating film 195, the lower spacers 440LS, and the device isolation film ST, may be provided. A gate contact 480, which is connected to the second gate electrodes 420 sequentially through the second part 195UP of the lower interlayer insulating film 195, the first part 195BP of the lower interlayer insulating film 195, and the gate spacers 440GS, may be provided.

A third etch stop film 175 may be additionally disposed between the second part 195UP of the lower interlayer insulating film 195 and the first interlayer insulating film 150. A first etch stop film 155 may be disposed between the first and second interlayer insulating films 150 and 160.

A first lower wiring structure 110 and a second lower wiring structure 120 may be provided within the first interlayer insulating film 150. A first upper wiring structure 210 and a second upper wiring structure 220 may be provided within the second interlayer insulating film 160. The detailed descriptions of the first and second lower wiring structures 110 and 120 and the first and second upper wiring structures 210 and 220 may be substantially the same as those provided earlier with reference to FIGS. 1 through 12.

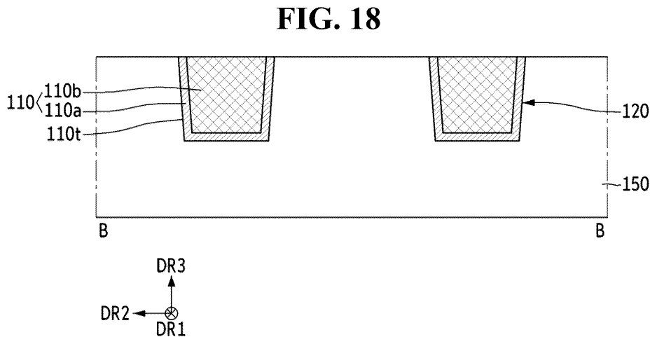

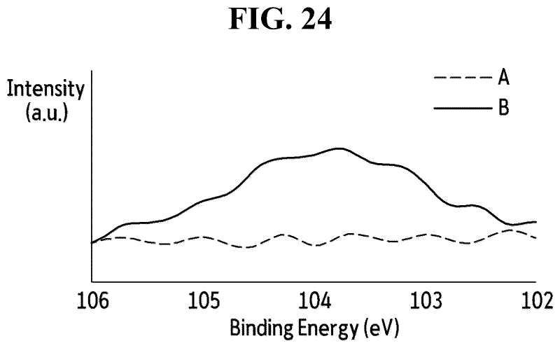

FIGS. 18 through 26 are diagrams illustrating intermediate stages of a method for manufacturing a semiconductor device according to some embodiments. For reference, FIG. 24 is an X-ray Photoelectron Spectroscopy (XPS) graph showing changes in Si concentration before and after an Si injection process.

Referring to FIG. 18, a first lower wiring structure 110 and a second lower wiring structure 120 are formed within a first interlayer insulating film 150.

Lower wiring trenches 110t are formed within the first interlayer insulating film 150. The first and second lower wiring structures 110 and 120 are formed within the lower wiring trenches 110t. The first and second lower wiring structures 110 and 120 may each include a lower barrier film 110a and a lower filling film 110b.

Referring to FIG. 19, a selective suppression film 60 may be formed on upper surfaces 110US and 120US of the first and second lower wiring structures 110 and 120.

The selective suppression film 60 may be formed on a conductive material. The selective suppression film 60 may not be formed on an insulating material. The selective suppression film 60 may not be formed on an upper surface 150US of the first interlayer insulating film 150.

The selective suppression film 60 may be formed on the upper surfaces of the lower filling film 110b and the lower barrier film 110a. Contrary to what is illustrated, the selective suppression film 60 may not be formed on the upper surface of the lower barrier film 110a.

The selective suppression film 60 includes an organic material. The selective suppression film 60 may prevent the deposition of a deposition material on the surface where the selective suppression film 60 is formed.

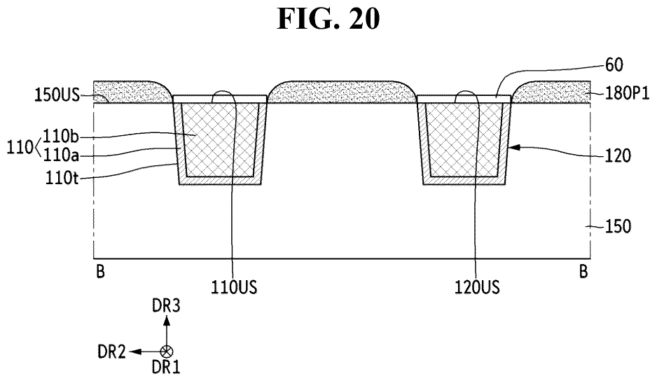

Referring to FIG. 20, in the state where the selective suppression film 60 is formed, a first pre-wiring isolation pattern 180P1 is formed on the upper surface 150US of the first interlayer insulating film 150.

The first pre-wiring isolation pattern 180P1 is not formed on the upper surfaces 110US and 120US of the first and second lower wiring structures 110 and 120, where the selective suppression film 60 is formed.

The first pre-wiring isolation pattern 180P1 may, for example, be formed on an insulating material using a selective deposition process. The first pre-wiring isolation pattern 180P1 may include aluminum oxide. The first pre-wiring isolation pattern 180P1 may be formed of aluminum oxide.

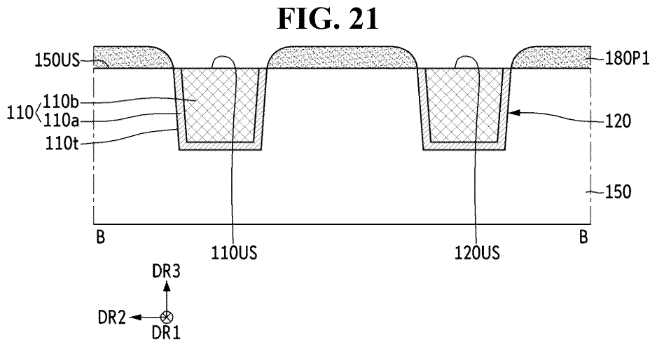

Referring to FIGS. 20 and 21, the selective suppression film 60 may be removed.

Through this, the upper surfaces 110US and 120US of the first and second lower wiring structures 110 and 120 are exposed.

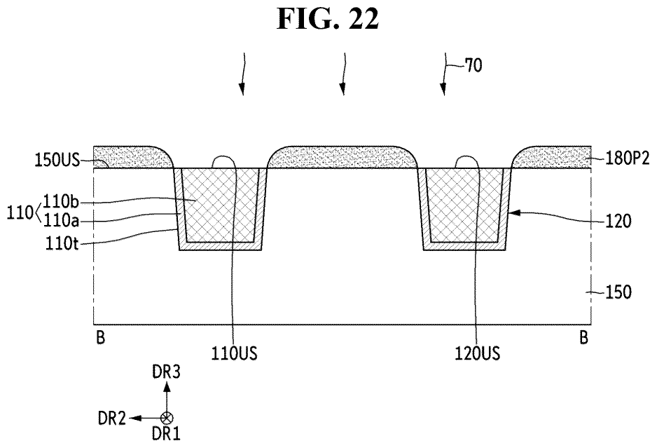

Referring to FIG. 22, through a preprocessing step 70, the first pre-wiring isolation pattern 180P1 may be transformed into a second pre-wiring isolation pattern 180P2.

The transformation of the first pre-wiring isolation pattern 180P1 involves breaking the bonds between Al and O in the aluminum oxide of the first pre-wiring isolation pattern 180P1, forming the second pre-wiring isolation pattern 180P2. The second pre-wiring isolation pattern 180P2 may include aluminum oxide with broken bonds between Al and O.

The preprocessing step 70 may include irradiating the first pre-wiring isolation pattern 180P1 with a collision gas. The type of collision gas is not particularly limited as long as it can break the bonds between Al and O in aluminum oxide.

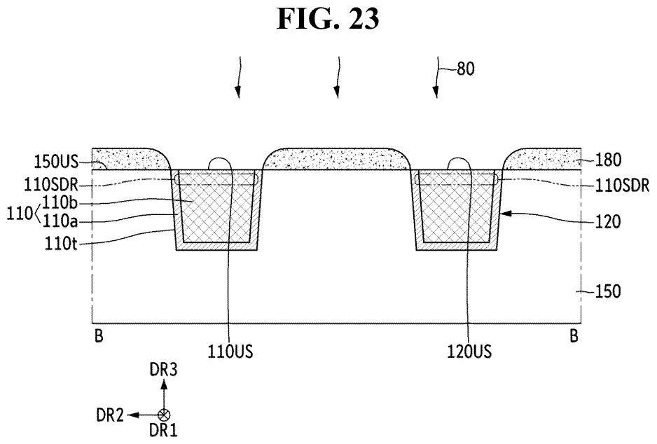

Referring to FIGS. 22 and 23, through an Si injection process 80, Si may be injected into at least a portion of the second pre-wiring isolation pattern 180P2.

Since the bonds between Al and O in the second pre-wiring isolation pattern 180P2 are broken, Si can be easily injected into the second pre-wiring isolation pattern 180P2. The injected Si may bond with Al and/or O to form a wiring isolation pattern 180. In this manner, a wiring isolation pattern 180 including aluminum silicate may be formed.

The Si injection process 80 may utilize a plasma process, but is not limited thereto.

During the Si injection process 80, Si may be injected near the upper surfaces 110US and 120US of the first and second lower wiring structures 110 and 120. Consequently, Si-doped regions 110SDR may be formed within the first and second lower wiring structures 110 and 120.

For example, by injecting Si into at least a portion of the second pre-wiring isolation pattern 180P2, the wiring isolation pattern 180 may be formed on the upper surface 150US of the first interlayer insulating film 150.

In FIG. 24, the dotted line A represents the binding energy in the first pre-wiring isolation pattern 180P1, and the solid line B represents the binding energy in the wiring isolation pattern 180 after the preprocessing step 70 and the Si injection process 80.

Before the preprocessing step 70 and the Si injection process 80, no peak corresponding to the silicon 2p orbital appears in the first pre-wiring isolation pattern 180P1, indicating no bonding of Si with other elements.

However, after the preprocessing step 70 and the silicon injection process 80, a peak corresponding to the Si 2p orbital appears in the wiring isolation pattern 180, confirming the bonding of Si with Al and/or O. This verifies that the wiring isolation pattern 180 includes aluminum silicate.

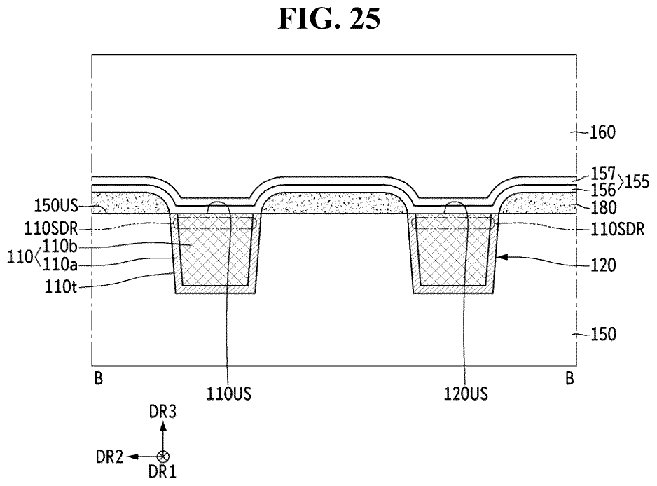

Referring to FIG. 25, a first etch stop film 155 and a second interlayer insulating film 160 may be sequentially formed on the wiring isolation pattern 180, the first lower wiring structure 110, and the second lower wiring structure 120.

The first etch stop film 155 may include a lower etch stop film 156 and an upper etch stop film 157.

Referring to FIG. 26, a first upper wiring trench 210t may be formed within the first etch stop film 155 and the second interlayer insulating film 160.

The first upper wiring trench 210t may expose the first lower wiring structure 110. During the formation of the first upper via trench 210V_t, the upper etch stop film 157 may, for example, be removed using a dry etching process. During the formation of the first upper via trench 210V_t, the lower etch stop film 156 may, for example, be removed using a wet etching process. During the removal of a portion of the lower etch stop film 156, the wiring isolation pattern 180, which includes aluminum silicate, may not be removed.

Thereafter, referring to FIGS. 2 and 3, a first upper wiring structure 210 and a second upper wiring structure 220, including a first upper barrier film 210a and a first upper filling film 210b, may each be formed within the first upper wiring trench 210t.

While the inventive concept has been particularly shown and described with reference to embodiments thereof, it will be understood that various changes in form and details may be made therein without departing from the spirit and scope of the present invention as set forth in the following claims.

What is claimed is:

1. A semiconductor device comprising:
a lower wiring structure disposed within a lower interlayer insulating film, and including a lower barrier film and a lower filling film disposed on the lower barrier film;
a wiring isolation pattern extending along an upper surface of the lower interlayer insulating film, in contact with the lower interlayer insulating film, and including aluminum silicate;
an upper interlayer insulating film disposed on the lower wiring structure and the wiring isolation pattern; and
an upper wiring structure disposed within the upper interlayer insulating film and connected to the lower wiring structure.

2. The semiconductor device of claim 1, further comprising:
an etch stop film disposed between the wiring isolation pattern and the upper interlayer insulating film, and between the lower wiring structure and the upper interlayer insulating film,
wherein the etch stop film includes aluminum.

3. The semiconductor device of claim 2, wherein:
the etch stop film includes a lower etch stop film, and an upper etch stop film disposed between the lower etch stop film and the upper interlayer insulating film, and
the lower etch stop film includes aluminum.

4. The semiconductor device of claim 3, wherein:
the lower etch stop film includes one of aluminum oxide or aluminum nitride, and
the upper etch stop film includes silicon oxycarbide.

5. The semiconductor device of claim 1, wherein:
the wiring isolation pattern has a single insulating layer structure, and
the wiring isolation pattern includes 1 at. % to 10 at. % of silicon.

6. The semiconductor device of claim 1, wherein:
the wiring isolation pattern includes a lower wiring isolation pattern, and an upper wiring isolation pattern disposed between the lower wiring isolation pattern and the upper interlayer insulating film, and
the upper wiring isolation pattern includes aluminum silicate.

7. The semiconductor device of claim 6, wherein the lower wiring isolation pattern includes aluminum oxide.

8. The semiconductor device of claim 1, wherein:
the lower wiring structure includes a silicon-doped region containing doped silicon, and
the silicon-doped region is disposed near an upper surface of the lower wiring structure.

9. The semiconductor device of claim 8, wherein:
the lower wiring structure further includes a lower capping film disposed on the lower filling film, and
the lower capping film includes the silicon-doped region.

10. The semiconductor device of claim 1, wherein the wiring isolation pattern is not disposed on the upper surface of the lower wiring structure.

11. A semiconductor device comprising:
a lower wiring structure disposed within a lower interlayer insulating film;
a wiring isolation pattern disposed on an upper surface of the lower interlayer insulating film and including a lower wiring isolation pattern and an upper wiring isolation pattern disposed on the lower wiring isolation pattern, wherein the lower wiring isolation pattern is in contact with the lower interlayer insulating film, and the upper wiring isolation pattern includes aluminum silicate;
an etch stop film disposed on the lower wiring structure and the wiring isolation pattern, and in contact with the upper wiring isolation pattern;
an upper interlayer insulating film disposed on the etch stop film; and
an upper wiring structure disposed within the upper interlayer insulating film and the etch stop film, and connected to the lower wiring structure.

12. The semiconductor device of claim 11, wherein the lower wiring isolation pattern includes aluminum oxide.

13. The semiconductor device of claim 11, wherein the upper wiring isolation pattern includes 1 at. % to 10 at. % of silicon.

14. The semiconductor device of claim 11, wherein:
the etch stop film includes a lower etch stop film, and an upper etch stop film disposed between the lower etch stop film and the upper interlayer insulating film, and
the lower etch stop film is in contact with the upper wiring isolation pattern and includes aluminum.

15. The semiconductor device of claim 14, wherein the lower etch stop film includes one of aluminum oxide or aluminum nitride.

16. The semiconductor device of claim 14, wherein the upper etch stop film includes silicon oxycarbide.

17. A semiconductor device comprising:
a first wiring structure disposed within a first interlayer insulating film;
a wiring isolation pattern extending along an upper surface of the first interlayer insulating film, in contact with the first interlayer insulating film, and including aluminum silicate;
a first etch stop film disposed on the first wiring structure and the wiring isolation pattern, and in contact with the wiring isolation pattern;
a second interlayer insulating film disposed on the first etch stop film;
a second wiring structure disposed within the second interlayer insulating film and the first etch stop film, and connected to the first wiring structure;
a second etch stop film disposed on the second wiring structure and the second interlayer insulating film, and in contact with an upper surface of the second interlayer insulating film;
a third interlayer insulating film disposed on the second etch stop film; and
a third wiring structure disposed within the third interlayer insulating film and the second etch stop film, and connected to the second wiring structure.

18. The semiconductor device of claim 17, wherein:
the wiring isolation pattern includes a lower wiring isolation pattern, and an upper wiring isolation pattern disposed between the lower wiring isolation pattern and the second interlayer insulating film,
the upper wiring isolation pattern includes aluminum silicate, and
the lower wiring isolation pattern includes aluminum oxide.

19. The semiconductor device of claim 17, wherein:
the first etch stop film includes a lower etch stop film, and an upper etch stop film disposed between the lower etch stop film and the second interlayer insulating film, and
the lower etch stop film is in contact with the wiring isolation pattern and includes aluminum.

20. The semiconductor device of claim 19, wherein:
the lower etch stop film includes one of aluminum oxide or aluminum nitride, and
the upper etch stop film includes silicon oxycarbide.
